(19) United States
(12) Patent Application Publication
(10) Pub. No.: US 2025/0209975 A1
(43) Pub. Date: Jun. 26, 2025

(54) LIGHT-EMITTING DEVICE AND METHOD FOR DRIVING THE SAME

(71) Applicant: NICHIA CORPORATION, Anan-shi (JP)

(72) Inventor: Hajime AKIMOTO, Anan-shi (JP)

(73) Assignee: NICHIA CORPORATION, Anan-shi (JP)

(21) Appl. No.: 18/984,435

(22) Filed: Dec. 17, 2024

(30) Foreign Application Priority Data
Dec. 25, 2023 (JP) 2023-218219

(51) Int. Cl. G09G 3/32

(52) U.S. Cl. CPC G09G 3/32; G09G 2300/0452; G09G 2320/0242; G09G 2320/0626; G09G 2320/0666

(57) ABSTRACT

A light-emitting device includes: a display comprising a plurality of pixels in which a plurality of first light-emitting elements each configured to emit light of a first light emission color and a plurality of second light-emitting elements each configured to emit light of a second light emission color different from the first light emission color are arranged in a predetermined pattern; and a lighting controller configured to supply a drive current to each of the plurality of first light-emitting elements and each of the plurality of second light-emitting elements and control a light emission period of each of the plurality of first light-emitting elements and each of the plurality of second light-emitting elements. A light emission color of a second light-emitting element of the plurality of second light-emitting elements is variable in accordance with a drive current supplied thereto.

### CROSS-REFERENCE TO RELATED APPLICATIONS

This application is based upon and claims priority to Japanese Patent Application No. 2023-218219, filed on Dec. 25, 2023, the entire contents of which are incorporated herein by reference.

### BACKGROUND

The present disclosure relates to a light-emitting device and a method for driving the light-emitting device.

Displays and surface light-emitting devices using semiconductor light-emitting elements, such as LEDs and LDs, are used. Here, to manufacture a full-color LED display, it is generally necessary to arrange sub-pixels of at least the three colors of RGB for each of pixels. However, in such a configuration, because it is necessary to provide at least three times as many of the sub-pixels as the pixels, this configuration is not suitable for high definition, and there are problems such as high cost and a decrease in yield due to the increase in the number of LEDs.

On the other hand, a micro-LED display has been reported that causes a single LED element to emit multicolor light (see JP 2021-52168 A). However, with respect to configuring a display using such a multicolor light-emitting micro-LED, an actual circuit configuration and driving method have not yet been reported. For example, it has not been easy in the current technology of controlling a multicolor light-emitting micro-LED to emit light in all chromaticity ranges of RGB.

It is an object of the present disclosure to provide a light-emitting device and a method for driving the light-emitting device that can implement appropriate light emission color control when configuring a light-emitting device, such as a display, using multicolor semiconductor light-emitting elements.

### SUMMARY

A light-emitting device according to an aspect of the present disclosure includes a display including a plurality of pixels in which a plurality of first light-emitting elements each capable of emitting light of a first light emission color and a plurality of second light-emitting elements each capable of emitting light of a second light emission color different from the first light emission color are arranged in a predetermined pattern; and a lighting controller configured to supply a drive current to each of the plurality of first light-emitting elements and the plurality of second light-emitting elements and control a light emission period. A light emission color of a second light-emitting element of the plurality of second light-emitting elements is variable in accordance with a drive current, and the lighting controller divides one frame into a first subframe and a second subframe and drives the plurality of first light-emitting elements and the plurality of second light-emitting elements, the one frame being a frame for causing the plurality of first light-emitting elements and the plurality of second light-emitting elements to emit light, the first subframe being a subframe for causing each of the plurality of first light-emitting elements to emit light, the second subframe being a subframe for causing each of the plurality of second light-emitting elements to emit light.

A method for driving a light-emitting device according to another aspect is for driving a light-emitting device including a display including a plurality of pixels in which a plurality of first light-emitting elements each capable of emitting light of a first light emission color and a plurality of second light-emitting elements each capable of emitting light of a second light emission color different from the first light emission color are arranged in a predetermined pattern, a light emission color of each of the plurality of second light-emitting elements being variable in accordance with a drive current, and a lighting controller configured to supply a drive current to each of the plurality of first light-emitting elements and the plurality of second light-emitting elements and control a light emission period, and includes, by the lighting controller, dividing one frame into a first subframe and a second subframe and driving the plurality of first light-emitting elements and the plurality of second light-emitting elements, the one frame being a frame for causing the plurality of first light-emitting elements and the plurality of second light-emitting elements to emit light, the first subframe being a subframe for causing each of the plurality of first light-emitting elements to emit light, the second subframe being a subframe for causing each of the plurality of second light-emitting elements to emit light.

With the above configuration, by combining a first light emission color and a second light emission color serving as a different light emission color in accordance with a drive current, thereby obtaining an advantage that multicolor light emission such as full-color emission is possible and simpler light emission control can be implemented.

### BRIEF DESCRIPTION OF THE DRAWINGS

FIG. 1 is a block diagram illustrating a light-emitting device according to a first embodiment.

FIG. 2 is a timing chart for lighting and driving a first light-emitting element and a second light-emitting element.

FIG. 3 is a block diagram illustrating an example in which a first control circuit and a second control circuit are provided in a pixel circuit.

FIG. 4 is a block diagram with an enlarged view illustrating of a display of the light-emitting device according to the first embodiment.

FIG. 5 is a schematic cross-sectional view illustrating an example of an element structure of a light-emitting element.

FIG. 6 is a schematic diagram illustrating a lighting image in a first subframe.

FIG. 7 is a schematic diagram illustrating a lighting image in a second subframe.

FIG. 8 is a functional block diagram illustrating a method for determining a drive current value and a PWM light emission period.

FIG. 9 is a chromaticity diagram for illustrating a procedure for determining a light emission chromaticity in FIG. 8.

FIG. 10A is a schematic diagram illustrating one pixel of the light-emitting device according to the first embodiment and FIG. 10B is a schematic diagram illustrating one pixel of a light-emitting device according to a second embodiment.

### DETAILED DESCRIPTION

Embodiments of the present disclosure are described in detail below with reference to the drawings. In the following description, terms indicating specific directions and positions (for example, “upper,” “lower,” and other terms including these terms) are used as necessary; however, the use of these terms is to facilitate the understanding of the invention with reference to the drawings, and the technical scope of the present disclosure is not limited by the meaning of these terms. Parts having the same reference characters appearing in a plurality of drawings indicate identical or equivalent parts or members.

The following embodiments show specific examples of the technical idea of the present disclosure, and the present disclosure is not limited to the following embodiments. Unless otherwise specified, the dimensions, materials, shapes, relative arrangements, and the like of constituent elements to be described below are not intended to limit the scope of the present disclosure only thereto, but rather to provide examples. The contents to be described in an embodiment and an example can be applied to another embodiment and another example. The size, positional relationship, and the like of the members illustrated in the drawings can be exaggerated to clarify the explanation.

### First Embodiment

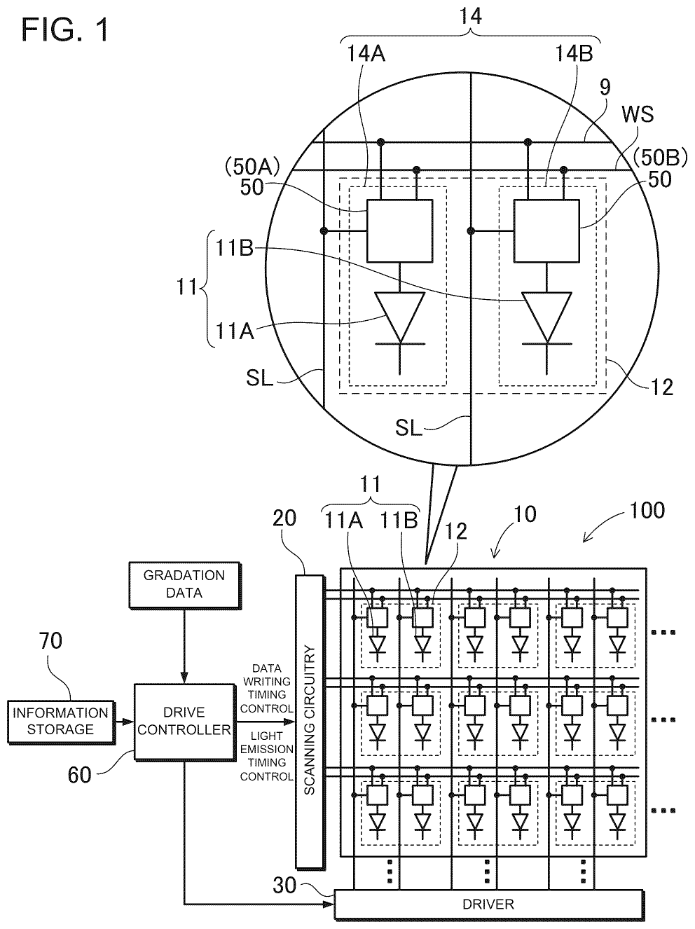

A block diagram of a light-emitting device 100 according to a first embodiment is illustrated in FIG. 1. The light-emitting device 100 illustrated in this drawing includes a display 10, a driver 30, lighting controllers 50, an information storage 70, a scanning circuitry 20, and a drive controller 60.

The display 10 includes a plurality of pixels 12 in which a plurality of first light-emitting elements 11A and a plurality of second light-emitting elements 11B are arranged in a predetermined pattern. Specifically, the plurality of first light-emitting elements 11A and second light-emitting elements 11B are arranged in a matrix. A period during which image data for one frame is displayed on a screen formed by the pixels 12 arranged in a matrix may be referred to as a vertical scanning period, and a period obtained by dividing the vertical scanning period by the number of rows of the screen may be referred to as a horizontal scanning period. For example, in the horizontal scanning period, a voltage value for power supply control of the pixels 12 arranged in a row direction (X-axis direction) is set, and a voltage value for analog image data is set. In the vertical scanning period, the scanning circuitry 20 that scans the pixels 12 is sequentially shifted in a column direction (Y-axis direction). The light-emitting device 100 in FIG. 1 adopts an active matrix driving method as a lighting driving method for lighting each pixel 12.

Each pixel 12 is constituted by one or more the first light-emitting elements 11A and one or more the second light-emitting elements 11B. In the example illustrated in FIG. 1, one pixel 12 includes one first light-emitting element 11A and one second light-emitting element 11B. However, the present disclosure is not limited to this configuration, and one pixel may be configured by a plurality of first light-emitting elements or a plurality of second light-emitting elements. By using a plurality of first light-emitting elements and second light-emitting elements, light emission luminance per pixel can be improved.

The first light-emitting elements 11A can emit light of a first light emission color. The first light emission color is, for example, blue.

The second light-emitting elements 11B can emit light of a second light emission color different from the first light emission color. The light emission color of the second light-emitting element 11B can be controlled in accordance with a drive current thereof. As such a second light-emitting element 11B, a multicolor light-emitting wavelength-tunable LED can be suitably used. The second light emission color is tunable from green to red, for example. In the present disclosure, the first light-emitting elements 11A and the second light-emitting elements 11B may be collectively referred to as light-emitting elements 11.

### Lighting Controller 50

The lighting controller 50 supplies a drive current to each of the plurality of first light-emitting elements 11A and the plurality of second light-emitting elements 11B to control a light emission period. In the example illustrated in the enlarged view of FIG. 1, the lighting controllers 50 are connected to a power supply line 9 and a write scanning line WS extending in a horizontal direction. The lighting controller 50 is driven by power supplied from the power supply line 9, and receives a power supply control signal and an analog image signal via the write scanning line WS. On the other hand, the lighting controller 50 is also connected to a signal line SL extending in a vertical direction, and receives the power supply control signal and the analog image signal.

The lighting controller 50 divides one frame for causing the plurality of first light-emitting elements 11A and the plurality of second light-emitting elements 11B to emit light into a first subframe for causing each of the plurality of first light-emitting elements 11A to emit light and a second subframe for causing each of the plurality of second light-emitting elements 11B to emit light, and drives the plurality of first light-emitting elements 11A and the plurality of second light-emitting elements 11B. For example, the first subframe is a B subframe for emitting blue light, and the second subframe is an RG subframe for emitting green light to red light.

With such a configuration, the light-emitting device 100 with a tunable light emission color can be efficiently driven. In particular, by limiting the light emission control of the second light-emitting elements 11B that can emit light of different light emission colors in accordance with a drive current to light emission control that is tunable only in a limited range of wavelengths, for example, from green light to red light without controlling light emission in the entire range of RGB, full-color light emission for each pixel can be achieved in combination with the first light emission color of the first light-emitting elements 11A, and simpler light emission control can be implemented.

In a multicolor light-emitting type LED having a tunable light emission wavelength, a light emission color is changed by a drive current. In other words, because the amount of drive current varies greatly depending on the light emission color, light emission luminance also varies greatly at the same time. For example, when a multicolor light-emitting type LED is used to display light of a short wavelength and light of a long wavelength on one display with luminance and light emission colors appropriately adjusted, a light emission period needs to be controlled in a range of approximately 3 to 30 times depending on the light emission wavelength. Therefore, to obtain sufficient light emission luminance by reducing an unnecessary non-lighting period, field sequential driving is desirably adopted to perform lighting in different subframes for each light emission color.

However, when the field sequential driving for changing the light emission color for each subframe is performed, color separation may occur particularly in a moving image and image quality may be significantly deteriorated. That is, in the field sequential driving, because pixels are of an active matrix type, a certain light emission duration needs to be secured after display data is written into a row selected by scanning. Thus, a scanning period and the light emission period of each of the rows are defined independently. Thus, in the field sequential method, the light emission is performed not on a row-by-row basis but on a sub-field-by-sub-field basis, which causes a problem that color separation occurs as a side effect.

On the other hand, in the light-emitting device 100 according to the first embodiment, as described above, the light-emitting elements 11 constituting one pixel are constituted by the first light-emitting elements 11A that can emit light of the first light emission color and the second light-emitting elements 11B that can emit light of the second light emission color, and the second light emission color is tunable, thereby suppressing the range of a necessary color change. Moreover, color separation is suppressed by using only blue light with low human visibility as another subframe. A detailed description is given below.

### First Light-Emitting Element 11A and Second Light-Emitting Element 11B

As the first light-emitting element 11A and the second light-emitting element 11B, a semiconductor light-emitting element such as a light-emitting diode (LED) or a semiconductor laser (LD) can be suitably used. As the LED, an LED in which one or more semiconductor layered bodies including light-emitting portions (hereinafter, also simply referred to as the “semiconductor layered body”) can be used. The semiconductor layered body has light-emitting characteristics, and such a semiconductor layered body is produced by layering a plurality of semiconductor layers, such as ZnS, SiC, GaN, GaP, InN, AlN, ZnSe, GaAsP, GaAlAs, InGaN, GaAlN, AlInGaP, AlInGaN or the like, on a substrate by liquid phase epitaxy, HVPE, or MOCVD, and forming an active layer on any one of the semiconductor layers. By selecting a material of the semiconductor layer and a mixed crystal ratio thereof, the light emission wavelength of the active layer can be selected variously from ultraviolet light to infrared light. In particular, in a case of a display device that can be suitably used outdoors, a semiconductor layered body that can emit light with high luminance is desired. Therefore, a nitride semiconductor is preferably selected as a material of a light-emitting portion that emits light with high luminance. For example, In_{X}Al_{Y}Ga_{1-X-Y}N (0≤X≤1, 0≤Y≤1, and X+Y≤1) or the like can be used as the material of the light-emitting portion.

In the first embodiment, a semiconductor light-emitting element such as a light-emitting diode or a semiconductor laser is used as the first light-emitting element 11A and the second light-emitting element 11B. A micro-LED may also be used as the light-emitting diode. The micro-LED has a chip size of 5 μm to 100 μm, and suitably 10 μm to 50 μm in consideration of light emission efficiency and the like.

The light emission color of the first light-emitting element 11A is fixed as the first light emission color. On the other hand, the light emission color of the second light-emitting element 11B is the second light emission color that is tunable. The second light-emitting element 11B emits light of a different light emission color in accordance with a drive current. For example, when driven by a first drive current, the second light-emitting element 11B emits light of a first light emission wavelength, for example red light, and when driven by a second drive current larger than the first drive current, the second light-emitting element 11B emits light of a second light emission wavelength shorter than the first light emission wavelength, for example greed light.

Each of the first light-emitting element 11A and the second light-emitting element 11B is connected to a plurality of common lines and a plurality of drive lines. The first light-emitting element 11A and the second light-emitting element 11B are connected to one of the plurality of common lines and one of the plurality of drive lines, respectively, and arranged in a matrix to constitute the display 10.

### Scanning Circuitry 20

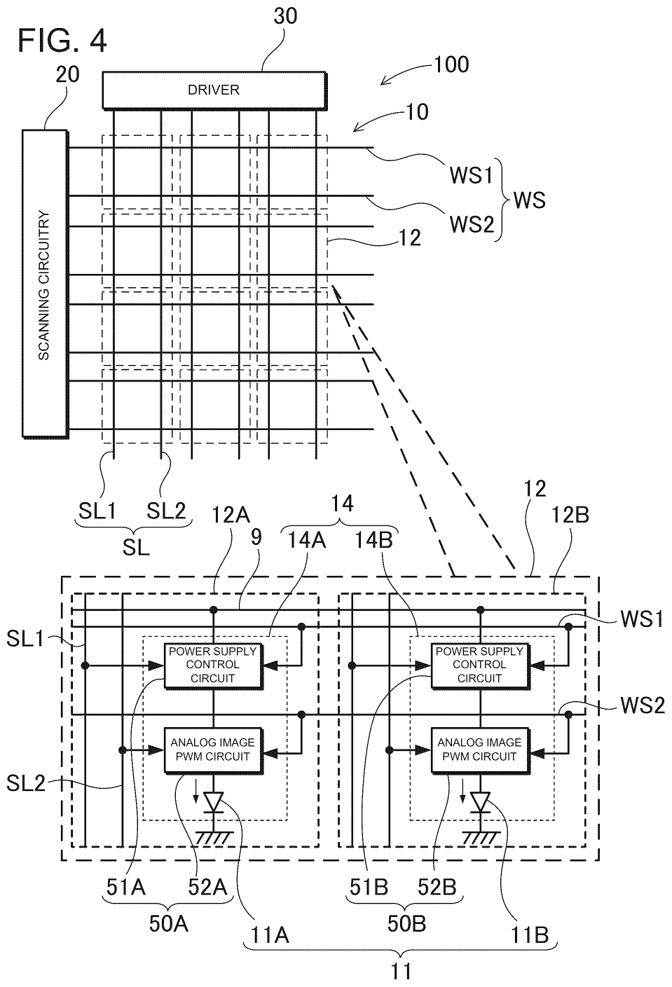

The scanning circuitry 20 is provided in a further left column of the leftmost column of the pixels 12 arranged in a matrix. The scanning circuitry 20 may be provided in a further right column of the rightmost column of the pixels 12 arranged in a matrix. As illustrated in FIG. 4, a power supply control signal write scanning line WS1 and an analog image signal write scanning line WS2 are provided for each row of the pixels as write scanning lines WS extending from the scanning circuitry 20. The power supply control signal write scanning line WS1 and the analog image signal write scanning line WS2 extend in the row direction.

The power supply control signal write scanning line WS1 supplies a first scanning signal being a digital signal for selecting, in the row direction, pixel circuits 14 (the lighting controller 50 and the light-emitting elements 11 in FIG. 1) to which desired voltage values are written, by the power supply control signal. A reference triangular wave signal is supplied to a selected pixel circuit 14, and the light-emitting element 11 of each pixel circuit 14 emits light during an ON period based on a written analog image signal voltage. The analog image signal write scanning line WS2 supplies a second scanning signal being a digital signal for selecting the pixel circuit 14 in the row direction when a voltage value is written by an analog image signal. A drive current value when the light-emitting element 11 emits light is set by a power supply control signal voltage (for details, refer to U.S. patent Ser. No. 10/885,834).

### Driver 30

The driver 30, as illustrated in FIG. 4, has a power supply control signal line SL1 and an analog image signal line SL2 extending as the signal lines SL in the vertical direction for each column of the pixels. The driver 30 supplies a power supply control signal to each pixel circuit 14 via the power supply control signal line SL1. The power supply control signal is an analog signal that can take a plurality of voltage values. The driver 30 supplies an analog image signal to each pixel circuit 14 via the analog image signal line SL2. The analog image signal is also an analog signal that can take a plurality of voltage values. Each pixel circuit 14, to which the power supply control signal is supplied and the voltage value is written, sets a drive current based on the written voltage value. Each pixel circuit 14, to which the analog image signal is supplied and the voltage value is written, sets a threshold voltage to be compared with the reference triangular wave signal based on the voltage value of the analog image signal, and sets a time width during which the pixel circuit 14 emits light (for details, refer to U.S. patent Ser. No. 10/885,834).

The driver 30 may generate the reference triangular wave signal to be supplied to each pixel circuit 14 for each column. Alternatively, the reference triangular wave signal may be separately provided as a reference triangular wave circuit in a row lower than the lowermost row of the matrix of the pixel circuits 14. The driver 30 or the reference triangular wave circuit distributes, for example, a reference triangular wave supplied from the outside of these circuits to the columns of the pixel circuits 14.

The driver 30 may include a storage unit. The storage unit can store luminance settings for a plurality of voltage values taken by the power supply control signal and luminance settings for a plurality of voltage values taken by the analog image signal. The relationship between the voltage values and the luminance settings can be adjusted and set by visually checking the luminance of the light-emitting element 11 constituting the pixel circuit 14. The γ correction can be performed by appropriately setting the relationship between the voltage values and the luminance settings. While gradation characteristics become linear in a digital PWM system, the fact that the γ correction can be applied to a signal is one of the advantages of this system. The storage unit is formed by, for example, an electrically rewritable storage circuit or the like.

### Drive Controller 60

The drive controller 60 further controls the operations of the scanning circuitry 20 and the driver 30. The scanning circuitry 20 and the driver 30 control the lighting controller 50 of each pixel. As illustrated in FIG. 3, each lighting controller 50 can include a first control circuit 51 and a second control circuit 52. The first control circuit 51 supplies a drive current to each of the first light-emitting element 11A and the second light-emitting element 11B. The second control circuit 52 controls the light emission periods of each of the first light-emitting element 11A and the second light-emitting element 11B. A configuration in which the light-emitting element is connected to the lighting controller 50 may be referred to as the “pixel circuit 14.” The first control circuit 51 is connected between the power supply line 9 and the second control circuit 52.

The pixel circuit 14 can be provided for each sub-pixel constituting one pixel 12. In the example of FIG. 1, the pixel circuit 14 includes a first sub-pixel circuit 14A and a second sub-pixel circuit 14B. The first sub-pixel circuit 14A drives the first light-emitting element 11A constituting a first sub-pixel. On the other hand, the second sub-pixel circuit 14B drives the second light-emitting element 11B constituting a second sub-pixel. In the example of FIG. 1, the first light-emitting element 11A as the first sub-pixel is allowed to emit blue light and the second light-emitting element 11B as the second sub-pixel is allowed to emit green to red light, so that the first sub-pixel and the second sub-pixel constitute one pixel 12.

### Information Storage 70

As described above, the second light-emitting element 11B is a multicolor light-emitting wavelength-tunable LED, and changes the second light emission color in accordance with a drive current. Therefore, a drive current value for driving the second light-emitting element 11B is to be determined in accordance with the second light emission color to be emitted by the second light-emitting element 11B. Therefore, the information storage 70 stores current-chromaticity information indicating the light emission color to be emitted by the second light-emitting element 11B and a correspondence relationship that determines a current value for emitting this color. The lighting controller 50 refers to the information storage 70 and determines the drive current of the second light-emitting element 11B corresponding to the second light emission color. The information storage 70 may include, for example, a storage element such as a current-chromaticity data memory for storing current-chromaticity data of the second light-emitting element 11B.

The information storage 70 may store current-chromaticity information based on an actually measured value of each second light-emitting element 11B arranged in the display 10, and also store current-chromaticity information generated by measuring a drive current and a light emission color of a light-emitting element equivalent to each second light-emitting element 11B arranged in the display 10. Alternatively, the information storage 70 may store current-chromaticity information that is recorded by statistically determining the relationship between the drive current and the light emission color of the second light-emitting element 11B. In the example of FIG. 1, the information storage 70 has a light emission chromaticity-drive current characteristic table of (G-R) and a light emission chromaticity-drive current-luminance characteristic table of (G-R).

The drive controller 60 controls the driver 30 to supply the drive current to each of the first light-emitting element 11A and the second light-emitting element 11B so that each of the first light-emitting element 11A and the second light-emitting element 11B emit light with a specific light emission color and light emission luminance. Because the first light emission color of the first light-emitting element 11A is fixed, the drive controller 60 controls the drive current corresponding to the light emission luminance. On the other hand, for the second light-emitting element 11B, the drive controller 60 determines a drive current value for driving each second light-emitting element 11B and an ON period, during which each second light-emitting element 11B emits light, by referring to the current-chromaticity information stored in the information storage 70 in accordance with a specific light emission color and gradation information for each second light-emitting element 11B, and performs the lighting driving of each second light-emitting element 11B by using the drive current from the driver 30.

The drive controller 60 also performs gradation control of the light emission luminance. For example, the drive controller 60 determines the drive current value of each of the first light-emitting element 11A and the second light-emitting element 11B by referring to the current-chromaticity information in accordance with the specific light emission color of each of the first light-emitting element 11A and the second light-emitting element 11B, and determines the ON period of each of the first light-emitting element 11A and the second light-emitting element 11B in accordance with the determined drive current value and with the predetermined gradation information for each of the first light-emitting element 11A and the second light-emitting element 11B.

The drive controller 60 may include a storage unit. The storage unit can store luminance settings for a plurality of voltage values taken by the power supply control signal and luminance settings for a plurality of voltage values taken by the analog image signal. The relationship between the voltage values and the luminance settings can be adjusted and set by visually checking the luminance of the light-emitting element constituting the pixel circuit 14. The γ correction can be performed by appropriately setting the relationship between the voltage values and the luminance settings. While gradation characteristics become linear in a digital PWM system, the fact that the γ correction can be applied to a signal is one of the advantages of this system. The storage unit is formed by, for example, an electrically rewritable storage circuit or the like.

The drive controller 60 may further cause the driver 30 to simultaneously perform lighting control of the first light-emitting element 11A and the second light-emitting element 11B in a state in which ON period information corresponding to one screen of each of the first light-emitting element 11A and the second light-emitting element 11B constituting the display 10 is written into the storage unit.

The drive controller 60 determines a drive current value for driving each first light-emitting element 11A and a light emission period, during which each first light-emitting element 11A emits light, in accordance with a light emission color and gradation information for each of the first light-emitting element 11A and the second light-emitting element 11B given from the outside. The drive controller 60 determines a drive current value for driving each second light-emitting element 11B and a light emission period, during which each second light-emitting element 11B emits light, by referring to the current-chromaticity information stored in the information storage 70. Subsequently, the drive controller 60 causes the driver 30 to perform lighting driving of each of the first light-emitting element 11A and the second light-emitting element 11B. With such a configuration, the lighting control of the display 10 constituted by the first light-emitting element 11A of a fixed wavelength type and the second light-emitting element 11B of a multicolor light-emitting type can be implemented.

With respect to the second light emission color of the second light-emitting elements 11B, when drive current values for emitting respective light emission colors of red (R), green (G), and blue (B) are IR, IG, and IB, respectively, the magnitude of the drive current values satisfies IR<IG<IB. Therefore, when the light emission periods of the maximum gradation of the respective colors are TR, TG, and TB, the relationship between the lengths of the maximum light emission periods of the respective colors during white display corresponding to full lighting satisfies TR>TG>TB.

However, when the second light emission color is varied in the entire range of R, G, and B, because the range in which the drive current of the second light-emitting element 11B is changed is widened, the control thereof is complicated. Therefore, by making the first light emission color and the second light emission color different from each other and causing the first light-emitting element 11A to responsible for the first light emission color, the range of the second light emission color for which the second light-emitting elements 11B is responsible can be limited, so that the control can be simplified. As for the assignment of the first light emission color and the second light emission color, preferably, the first light emission color is blue and the second light emission color is tunable from green to red or the second light emission color is blue to green and the first light emission color is red so that the second light emission color can be continuously changed. Among them, because the drive current value (IB) for blue light emission is the maximum for the drive current value of the multicolor light-emitting type LED, the drive current value of the second light-emitting element 11B can be more preferably suppressed by setting the first light emission color to blue and the second light emission color to green to red.

In addition, the above assignment of the light emission colors can solve the problem that color separation occurs when field sequential driving is performed to change the light emission color for each subframe. That is, by causing the first light-emitting element 11A to emit blue light and causing the second light-emitting element 11B to emit green to red light, the light emission of the first light-emitting element 11A and the second light-emitting element 11B can be divided into the B subframe and the GR subframe that is tunable between (G-R), and the first light-emitting element 11A and the second light-emitting element 11B can be driven. Because the resolution of the human eye is low with respect to blue light, even though the blue light is allocated to another subframe and field sequential driving is performed, color separation is hardly recognized, thereby avoiding the occurrence of color separation, reducing an unnecessary non-lighting period while using a multicolor light-emitting type LED, and obtaining sufficient light emission luminance.

Accordingly, in the light-emitting device 100 according to the first embodiment, the first light-emitting element 11A emits blue light of the first light emission color, and the second light-emitting element 11B emits light of any color from red to green (RG) of the second light emission color. Thus, full-color light emission can be implemented by the first light-emitting element 11A and the second light-emitting element 11B without causing color separation. PWM can be used for the gradation control of each of the light emission colors. Here, products of the maximum light emission periods and the drive current values by the PWM driving satisfy R>G>B. This is because light emission luminance efficiency of the second light-emitting element 11B is higher in the order of R<G<B.

The above description is given on the assumption that the second light emission color of the second light-emitting element 11B can be varied in the entire range of R, G, and B; however, by manufacturing the second light-emitting element 11B so that the second light emission color can be varied only in the range from R to G, advantages such as simplification of a manufacturing process and cost reduction is obtained. For example, the manufacturing process margin of the second light-emitting element 11B can be made wider.

### Timing Chart

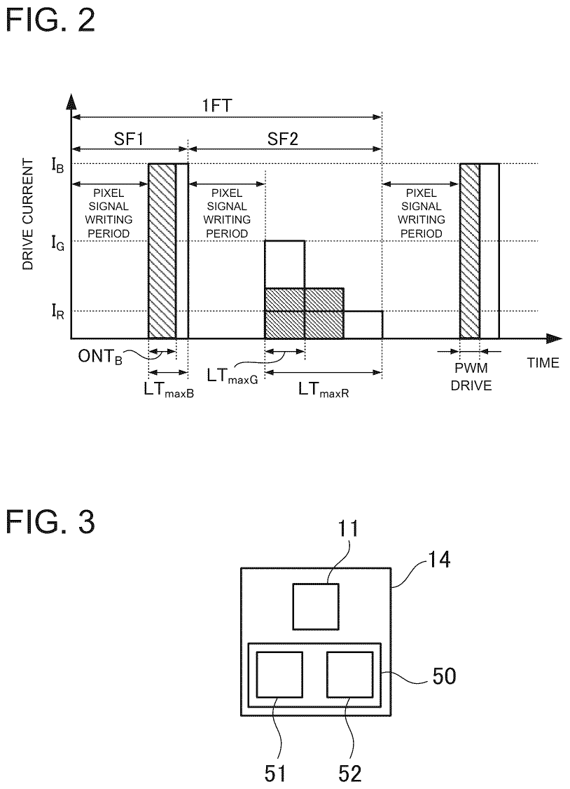

FIG. 2 is a timing chart showing lighting timings of each of the RGB colors of the light-emitting device 100 illustrated in FIG. 1. One frame period FT is divided into a first subframe period SF1 in which the first light-emitting element 11A emits light and a second subframe period SF2 in which the second light-emitting element 11B emits light. The first subframe period SF1 is the B subframe in which blue light is emitted, and the second subframe period SF2 is the GR subframe in which light of any color from green to red is emitted. In the B subframe, a current having a value corresponding to blue light, for example, 470 nm, is supplied to the first light-emitting element 11A. In the GR subframe, because light is changed from green light to red light, a current having a value in a range from a current value corresponding to green light, for example, 515 nm to a current value corresponding to red light, for example, 630 nm is supplied to the second light-emitting element 11B. That is, a current having the maximum value for causing the first light-emitting elements 11A to emit light is supplied in the B subframe, whereas a drive current corresponding to the second light emission color is supplied in the GR subframe. In other words, in the GR subframe, the light emission color is controlled by the vertical axis (drive current) in FIG. 2.

In each subframe, the light emission luminance is controlled by PWM control. By changing an ON period ONT within a maximum light emission period LTmax, the luminance can be adjusted to a desired value by changing a current integrated value while supplying a current at a maximum value. A maximum light emission period of blue light is denoted by LTmaxB, and the ON period of blue light is denoted by ONTB. On the other hand, in a maximum light emission period from green light to red light, the maximum light emission period of green light is denoted by LTmaxG and the maximum light emission period of red light is denoted by LTmaxR. The ON period ONT is included in the maximum light emission period. Actually, as shown by oblique lines in FIG. 2, once the drive current value (vertical axis) is determined in accordance with a desired light emission color, the horizontal axis is determined in accordance with the luminance. In this way, in both the B subframe and the (G-R) subframe, luminance control is performed by the horizontal axis (ON period) in FIG. 2.

A pixel signal writing period is provided in each subframe, and PWM control is performed after the pixel signal writing period. In the pixel signal writing period, a pixel signal for one screen of each of the first light-emitting element 11A and the second light-emitting element 11B is written to a pixel memory. The driver 30 controls lighting of the light-emitting element 11 by referring to the pixel signal written to the pixel memory. The pixel memory is provided in the lighting controller 50 of the pixel circuit 14.

As illustrated in FIG. 3, the lighting controller 50 includes the first control circuit 51 and the second control circuit 52. The first control circuit 51 performs current driving in accordance with a light emission color. The second control circuit 52 performs PWM control. Specifically, in performing the PWM control, the second control circuit 52 sets a time width for supplying a current to the light-emitting element 11 based on the result of comparison between a first signal including a triangular wave signal and a first DC voltage set in a predetermined period. Based on a second DC voltage set in a period different from the predetermined period, the first control circuit 51 controls a current value to be supplied by the lighting controller 50.

As illustrated in FIG. 4, the power supply control signal write scanning line WS1 and the analog image signal write scanning line WS2 extend from the scanning circuitry 20, and are connected to each pixel 12. The power supply control signal line SL1 and the analog image signal line SL2 extend from the driver 30, and are connected to each pixel 12. The driver 30 is a driver IC that processes a power supply control signal and an analog image signal. The power supply control signal write scanning line WS1 and the analog image signal write scanning line WS2 are connected to a TFT circuit provided on a mounting substrate together with the pixel circuit 14. The TFT is made of low-temperature polycrystalline Si or an oxide semiconductor.

Each pixel 12 includes a plurality of sub-pixels as illustrated in an enlarged view of main components of FIG. 4. The pixel 12 includes a first sub-pixel 12A and a second sub-pixel 12B. Each sub-pixel includes the light-emitting element 11. Specifically, the first sub-pixel 12A includes a first lighting controller 50A and the first light-emitting element 11A constituting the first sub-pixel 12A. The second sub-pixel 12B includes a second lighting controller 50B and the second light-emitting element 11B constituting the second sub-pixel 12B. Each pixel circuit 14 includes the lighting controller 50. The first lighting controller 50A includes a first control circuit 51A and a second control circuit 52A. The second lighting controller 50B includes a first control circuit 51B and a second control circuit 52B. The first control circuits 51A and 51B supply drive currents to the first light-emitting element 11A and the second light-emitting element 11B, respectively. On the other hand, the second control circuits 52A and 52B control the light emission periods of the first light-emitting element 11A and the second light-emitting element 11B, respectively. The first control circuits 51A and 51B are power supply control circuits, and the second control circuits 52A and 52B are analog image PWM circuits. The first control circuits (power supply control circuits) 51A and 51B are connected to the power supply line 9 and the power supply control signal line SL1. A power supply control signal write timing is input from the power supply control signal write scanning line WS1. On the other hand, the second control circuits (analog image PWM circuits) 52A and 52B are connected in series to the power supply line 9 via the first control circuits 51A and 51B, respectively. The second control circuits 52A and 52B are also connected to the analog image signal line SL2. An analog image signal write timing is input from the analog image signal write scanning line WS2. In this way, each of the light-emitting elements 11 is connected to the power supply line 9 via the power supply control circuit and the analog image PWM circuit. A drive current value is controlled by the power supply control circuit, and a drive time is controlled by the analog image PWM circuit.

FIG. 4 illustrates an example in which each of the first sub-pixel 12A and the second sub-pixel 12B includes one LED; however, the present disclosure is not limited to this configuration and each sub-pixel may include a plurality of light-emitting elements such as LEDs. For example, when a plurality of light-emitting elements are used for the purpose of increasing luminance or the like, two or more light-emitting elements may be connected in series.

### LED

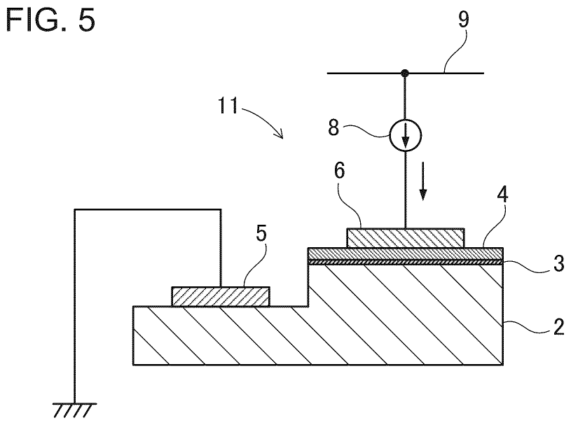

FIG. 5 illustrates an example of an element structure in the case of using an LED as the light-emitting element 11. The light-emitting element 11 illustrated in FIG. 5 includes an n-type semiconductor layer 2, an active layer 3, a p-type semiconductor layer 4, an n-side electrode 5, and a p-side electrode 6. The active layer 3 may have a multiple quantum well structure (MQW) or the like. The light-emitting element 11 is connected to a pixel drive circuit 8 such as a DC power supply, and emits light upon receiving a drive current supplied from the power supply line 9. The light emission period of the first light-emitting element 11A is controlled by a specific drive current. The light emission color of the first light-emitting element 11A is fixed to blue. The second light emission color of the second light-emitting element 11B is controlled by a drive current, and the light emission period of the second light-emitting element 11B is controlled by the drive current. The second light emission color is tunable to any color from green to red.

### B Subframe

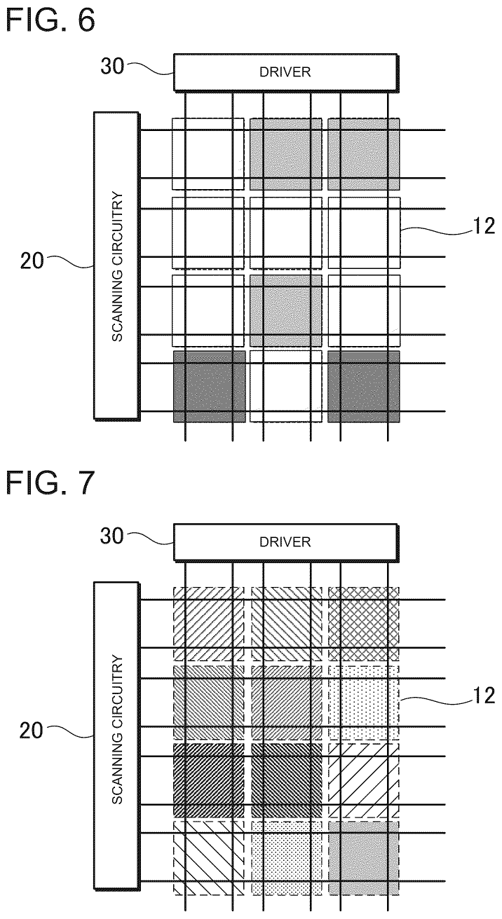

FIG. 6 illustrates a lighting image in the B subframe using such a display 10 and FIG. 7 illustrates a lighting image in the GR subframe using such a display 10. In these drawings, each pixel 12 is illustrated in a tile shape. In the B subframe, the luminance is different between the pixels 12, but the chromaticity is constant. The luminance gradation is controlled by PWM. The difference in the density of each pixel 12 in FIG. 6 represents the difference in the average luminance in the subframe.

### GR Subframe

On the other hand, in the GR subframe, both the luminance and the chromaticity are tunable between the pixels 12. In the (G-R) subframe, a current value supplied to the second light-emitting element 11B and the second light emission color, that is, the chromaticity, are controlled in the range of (G-R). Specifically, in each pixel 12, the lighting controller 50 acquires the RGB chromaticity by referring to the information storage 70. The chromaticity of B, that is, the first light emission color emitted by the first light-emitting element 11A is uniquely determined. On the other hand, the second light emission color of the second light-emitting element 11B is to be determined. First, a light emission color at the time of (G-R) wavelength variation and a luminance ratio of B to (G-R) are determined from a chromaticity signal to be displayed so as to correspond to a color at the time of B emission. Subsequently, a light emission intensity corresponding to a luminance signal to be displayed is determined from the chromaticity of the light emission color and the luminance ratio.

### Method for Driving Light-Emitting Device

An example of a method for driving the light-emitting device is described below. The following describes a process in which the lighting controller 50 divides one frame for causing the plurality of first light-emitting elements 11A and the plurality of second light-emitting elements 11B to emit light into a first subframe and a second subframe and drives the plurality of first light-emitting elements 11A and the plurality of second light-emitting elements 11B. In the first subframe, each of the plurality of first light-emitting elements 11A is caused to emit light. Because blue light is emitted as the first light emission color in the first subframe, it is referred to as the B subframe. In the second subframe, each of the plurality of second light-emitting elements 11B is caused to emit light. Because the second light emission color is emitted in the second subframe, it is referred to as the RG subframe.

The lighting controller 50 causes the first control circuit 51 to supply a drive current to each of the first light-emitting element 11A and the second light-emitting element 11B, and causes the second control circuit 52 to control a light emission period of each of the first light-emitting element 11A and the second light-emitting element 11B. The step of driving, by the lighting controller 50, the plurality of first light-emitting elements 11A and the plurality of second light-emitting elements 11B includes a step of determining the second light emission color and a luminance ratio of the first light-emitting element 11A and the second light-emitting element 11B from a chromaticity signal and a luminance signal to be displayed by the pixel 12 so as to correspond to the first light emission color, a step of determining a light emission intensity corresponding to a luminance signal to be displayed based on the chromaticity of the second light emission color and the luminance ratio, a step of supplying, by the first control circuit 51, a drive current having a value corresponding to a light emission color to the corresponding one of the first light-emitting element 11A and the second light-emitting element 11B by referring to the information storage 70, and a step of controlling, by the second control circuit 52, a light emission period of the drive current to be supplied to each of the first light-emitting element 11A and the second light-emitting element 11B in accordance with the determined light emission intensity.

In the first subframe, the first control circuit 51 controls the drive current of each of the plurality of first light-emitting elements 11A to be constant, and the second control circuit 52 controls the light emission intensity by PWM control. The drive current of the first light-emitting element 11A is set to a drive current value at which blue light emission is highly efficient. For example, it is a rated current value.

On the other hand, in the second subframe, the first control circuit 51 controls a light emission color by a current value for driving each of the plurality of second light-emitting elements 11B. The second control circuit 52 controls the light emission period of the current value of each of the plurality of second light-emitting elements 11B controlled by the first control circuit 51, thereby controlling the luminance. Specifically, the second control circuit 52 determines the chromaticity of the second light emission color and the luminance ratio of the first light-emitting element 11A and the second light-emitting element 11B from the chromaticity signal and the luminance signal to be displayed by each pixel 12 so as to correspond to the first light emission color. Subsequently, the second control circuit 52 determines the light emission intensity corresponding to the luminance signal to be displayed by the second light-emitting element 11B, based on the chromaticity of the second light emission color and the luminance ratio. In response to this, the first control circuit 51 supplies a drive current having a value corresponding to the light emission color of each of the first light-emitting element 11A and the second light-emitting element 11B to each of the first light-emitting element 11A and the second light-emitting element 11B by referring to the information storage 70. The second control circuit 52 controls the light emission period of each of the first light-emitting element 11A and the second light-emitting element 11B in accordance with the determined light emission intensity.

### Method for Determining Drive Current Value and PWM Light Emission Period

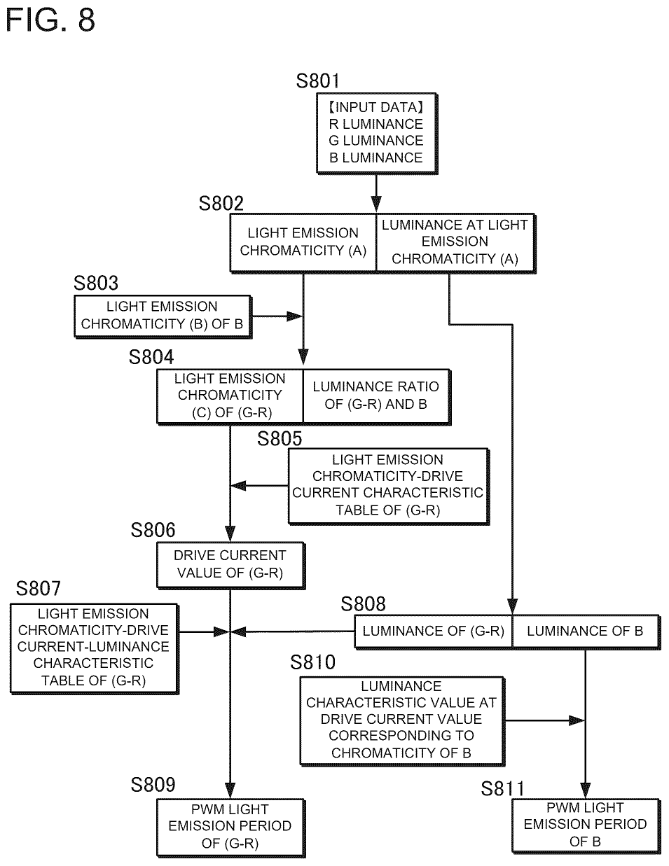

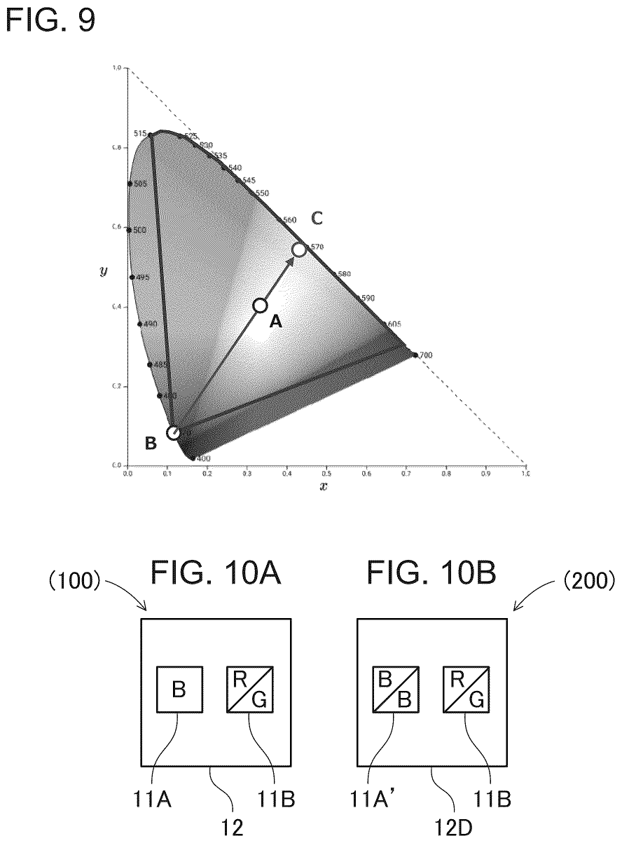

Details of the procedure for determining the drive current value and the PWM light emission period of each of the first light-emitting element 11A and the second light-emitting element 11B are described with reference to the functional block diagram of FIG. 8 and the chromaticity diagram of FIG. 9.

First, in step S801, the drive controller 60 acquires image data from an external source. The input data includes R luminance, G luminance, and B luminance.

Subsequently, in step S802, a specific light emission chromaticity and luminance are determined for each pixel. Any light emission chromaticity to be emitted is represented by a point A on the chromaticity diagram of FIG. 9. In this chromaticity diagram, because the first light-emitting element 11A emits blue light as the first light emission color, it is fixed at a point B near the lower left apex of the chromaticity diagram. On the other hand, because the second light-emitting element 11B emits light of a second light emission color between green and red, the second light emission color is represented on the chromaticity diagram at a point C between green near the upper apex and red near the right apex of the chromaticity diagram. Accordingly, the chromaticity at the point A expressed by the mixed light of the first light-emitting element 11A and the second light-emitting element 11B can be expressed by the points B and C. In other words, the light emission color of the second light-emitting element 11B is adjusted to adjust the point C to express the chromaticity at the point A. Moreover, the luminance ratio of B to (G-R) is determined with respect to a predetermined point A in consideration of the balance of the luminance between the first light-emitting element 11A and the second light-emitting element 11B. Thus, the drive current value and the light emission period of the second light-emitting element 11B at the point C are determined.

In accordance with the above-described idea, by considering the light emission chromaticity (B) of B from the light emission chromaticity (A) of A determined in step S802 (step S803), the light emission chromaticity (C) of (G-R) and the luminance ratio of B to (G-R) are determined (step S804). When the luminance ratio of B to (G-R) is determined in step S804, the luminance of (G-R) and the luminance of B are inevitably obtained from the luminance at the light emission chromaticity (A) in step S802 (step S808).

On the other hand, when the light emission chromaticity (C) of (G-R) is determined in step S804, the light emission chromaticity-drive current characteristic table of (G-R) stored in the information storage 70 is referenced (step S805) to determine the drive current value of (G-R) (step S806).

When the drive current value of (G-R) is determined in step S806, the light emission chromaticity-drive current-luminance characteristic table of (G-R) (step S807) stored in the information storage 70 and the luminance of (G-R) (step S808) are referenced to determine the PWM light emission period of (G-R) (step S809).

On the other hand, from the luminance of B obtained in step S808, the PWM light emission period of B is determined with reference to the luminance characteristic value (step S810) at the drive current value corresponding to the chromaticity of B (step S811). In this way, the drive current values of the second light-emitting elements 11B and the PWM light emission periods of the first light-emitting elements 11A and the second light-emitting elements 11B are determined. As illustrated in FIG. 2 described above, the drive current value of the first light-emitting element 11A is the maximum value of the drive current value for causing the first light-emitting element 11A to emit light.

In the light-emitting device 100 according to the first embodiment described above, the first light-emitting element 11A and the second light-emitting element 11B are provided for each pixel 12. As illustrated in FIG. 10A, the first light-emitting element 11A is a fixed-wavelength light-emitting element for blue light, and the second light-emitting element 11B is a tunable-wavelength light-emitting element for green to red light. In this example, one first light-emitting element 11A and one second light-emitting element 11B are provided in each pixel 12; however, a plurality of first light-emitting elements and/or a plurality of second light-emitting elements may be provided in each pixel. This makes it possible to increase the light emission luminance.

In the first embodiment, the one frame period FT is divided into the first subframe period SF1 in which the first light-emitting element 11A emits light and the second subframe period SF2 in which the second light-emitting element 11B emits light, the first subframe period SF1 is the B subframe in which blue light is emitted, the second subframe period SF2 is the GR subframe in which light of any color from green to red is emitted, and FIG. 2 illustrates a state in which the first subframe period SF1 precedes the second subframe period SF2. However, the present disclosure is not limited to this configuration. For example, the second subframe, which is the GR subframe for emitting light of any color from green to red, may precede the first subframe that is the B subframe for emitting blue light. As described above, the human visual sensitivity perceives brightness in the GR subframe and perceives colors by combining the GR subframe and the B subframe, but it is the timing at which brightness is perceived that has the time resolution. Accordingly, advancing the GR subframe makes it is possible to obtain an effect of suppressing the delay of the timing perceived by a human with respect to video display data input to a display system. In this case, the preceding GR subframe may be rephrased as the first subframe, and the B subframe may be rephrased as the second subframe.

### Second Embodiment

The present disclosure is not limited to the configuration in which the first light-emitting element has a fixed wavelength and the second light-emitting element has a tunable wavelength, and the first light-emitting element may also be a tunable-wavelength light-emitting element. Such an example is illustrated in FIG. 10B as a light-emitting device 200 according to a second embodiment. FIGS. 10A and 10B illustrate examples in which a fixed-wavelength light-emitting element is indicated by a square and tunable-wavelength light-emitting elements are each indicated by a square with a diagonal line. The tunable-wavelength light-emitting element is driven by tuning a light emission wavelength in a range from a light emission color in an upper left region to a light emission color in a lower right region of the square separated by a diagonal line. The reason why the square is separated by a diagonal line is merely to indicate a change in a light emission wavelength, and it is not intended that a light-emitting region of the light-emitting element is physically divided by a diagonal line to emit light in different light emission colors for each region.

In the light-emitting device according to the first embodiment illustrated in FIG. 10A, the first light-emitting element 11A is a fixed-wavelength light-emitting element, and the second light-emitting element 11B is a tunable-wavelength light-emitting element, which is used by tuning a light emission wavelength in the range of light emission colors from red R to green B. On the other hand, in the second embodiment illustrated in FIG. 10B, a tunable-wavelength light-emitting element is also used as a first light-emitting element 11A′, but the first light-emitting element 11A′ is driven with its light emission wavelength fixed to blue B.

Regardless of the light emission wavelength range actually driven in this way, the tunable range of light emission wavelength of the tunable-wavelength light-emitting element used as the first light-emitting element 11A′ may be B-G, B-R, or B-Y as long as B is included in the tunable range of light emission wavelength. In this case, when the tunable-wavelength light-emitting element used as the first light-emitting element 11A′ and the tunable-wavelength light-emitting element used as the second light-emitting element 11B are light-emitting elements with both B-R tunable emission wavelength ranges regardless of the light emission wavelength range actually driven, each pixel 12D can be formed using single-specification light-emitting elements, so that the manufacturing process of the pixel 12D can be simplified.

In addition, to cause the tunable-wavelength first light-emitting element 11A′ to emit light with the first light emission color of blue fixed, the information storage 70 stores current-chromaticity information and the like of the first light-emitting element 11A′ as well as the second light-emitting element 11B. The lighting controller 50 determines a drive current of the first light-emitting element 11A′ corresponding to the first light emission color by referring to the information storage 70. Moreover, when the first light-emitting element 11A′ is of a tunable-wavelength type, the wavelengths of blue light can be adjusted. For example, variations in the light emission wavelength of the first light-emitting element 11A′ can be corrected among the pixels 12D and the wavelengths of blue light of the pixels 12D can be equalized.

The above examples describe an active matrix driving method, but the present disclosure can also be applied to a passive matrix driving method.

A light-emitting device of the present disclosure can be suitably used for a medium-sized or a large-sized display, an indicator, signage, or the like, for example.

### REFERENCE CHARACTERS LIST

100, 200 Light-emitting device
2 n-type semiconductor layer
3 Active layer
4 p-type semiconductor layer
5 n-side electrode
6 p-side electrode
8 Pixel drive circuit
9 Power supply line
10 Display
11 Light-emitting element; 11A, 11A′ First light-emitting element; 11B Second light-emitting element
12, 12B, 12D Pixel; 12A First sub-pixel; 12B Second sub-pixel
14 Pixel circuit; 14A First sub-pixel circuit; 14B Second sub-pixel circuit
20 Scanning circuitry
30 Driver
50, 50A, 50B Lighting controller
51, 51A, 51B First control circuit; 52, 52A, 52B Second control circuit
60 Drive controller
70 Information storage
WS Write scanning line
WS1 Power supply control signal write scanning line; WS2 Analog image signal write scanning line
SL Signal line; SL1 Power supply control signal line; SL2 Analog image signal line

What is claimed is:

1. A light-emitting device comprising:
a display comprising a plurality of pixels in which a plurality of first light-emitting elements each configured to emit light of a first light emission color and a plurality of second light-emitting elements each configured to emit light of a second light emission color different from the first light emission color are arranged in a predetermined pattern; and
a lighting controller configured to supply a drive current to each of the plurality of first light-emitting elements and each of the plurality of second light-emitting elements and control a light emission period of each of the plurality of first light-emitting elements and each of the plurality of second light-emitting elements,
wherein a light emission color of a second light-emitting element of the plurality of second light-emitting elements is variable in accordance with a drive current supplied thereto, and
wherein the lighting controller is configured to:
divide one frame, in which the lighting controller drives the plurality of first light-emitting elements and the plurality of second light-emitting elements, into a first subframe and a second subframe,
drive the plurality of first light-emitting elements in the first subframe, and
drive the plurality of second light-emitting elements in the second subframe.

2. The light-emitting device according to claim 1, further comprising:
an information storage configured to store current-chromaticity information for determining a drive current value to light each of a first light-emitting element of the plurality of first light-emitting elements and the second light-emitting element in accordance with a specific light emission color of each of the plurality of pixels, and
wherein the lighting controller is configured to control the plurality of first light-emitting elements and the plurality of second light-emitting elements based on the current-chromaticity information stored in the information storage so that each of the plurality of first light-emitting elements and the plurality of second light-emitting elements emits light of a specific light emission color and light emission luminance.

3. The light-emitting device according to claim 2, wherein:
the lighting controller comprises:
a first control circuit configured to supply a drive current to each of the first light-emitting element and the second light-emitting element, and
a second control circuit configured to control a light emission period of each of the first light-emitting element and the second light-emitting element.

4. The light-emitting device according to claim 3, wherein one or more lighting controllers are provided for each of the plurality of pixels.

5. The light-emitting device according to claim 1, wherein each of the plurality of pixels comprises at least one of the plurality of first light-emitting elements and at least one of the plurality of second light-emitting elements.

6. The light-emitting device according to claim 1, wherein the first light emission color is blue.

7. The light-emitting device according to claim 6, wherein the first light emission color has a fixed wavelength.

8. The light-emitting device according to claim 1, wherein the second light emission color is tunable between green and red in accordance with a drive current to the second light emitting element.

9. The light-emitting device according to claim 3, wherein:
the first control circuit is configured to supply a drive current having a value corresponding to a light emission color of each of the first light-emitting element and the second light-emitting element to the corresponding one of the first light-emitting element and the second light-emitting element by referring to the information storage, and
the second control circuit is configured to control a light emission period of each of the first light-emitting element and the second light-emitting element in accordance with a light emission intensity corresponding to a luminance signal to be displayed by the second light-emitting element, the light emission intensity being determined based on a chromaticity of the second light emission color and a luminance ratio of the first light-emitting element and the second light-emitting element, the chromaticity of the second light emission color and the luminance ratio being determined from a chromaticity signal and a luminance signal which are a basis of chromaticity and luminance to be displayed by each pixel so as to correspond to the first light emission color respectively, in the second subframe.

10. The light-emitting device according to claim 1, wherein:
the lighting controller is configured to set a time width for supplying a current to each of the first light-emitting element and the second light-emitting element based on comparison between a first signal comprising a triangular wave signal and a first DC voltage set in a predetermined period, and
the lighting controller is configured to control a current value to be supplied based on a second DC voltage set in a period different from the predetermined period.

11. A method for driving a light-emitting device comprising a display comprising a plurality of pixels in which a plurality of first light-emitting elements each configured to emit light of a first light emission color and a plurality of second light-emitting elements each configured to emit light of a second light emission color different from the first light emission color are arranged in a predetermined pattern, a light emission color of each of the plurality of second light-emitting elements being variable in accordance with a drive current supplied thereto, and a lighting controller configured to supply a drive current to each of the plurality of first light-emitting elements and the plurality of second light-emitting elements and control a light emission period of each of the plurality of first light-emitting elements and the plurality of second light-emitting elements, the method comprising:
dividing one frame, in which the lighting controller drives the plurality of first light-emitting elements and the plurality of second light-emitting elements, into a first subframe and a second subframe,
driving the plurality of first light-emitting elements in the first subframe, and
driving the plurality of second light-emitting elements in the second subframe.

12. The method for driving a light-emitting device according to claim 11, wherein:
the driving the plurality of first light-emitting elements and the plurality of second light-emitting elements with the lighting controller comprises:
determining the second light emission color and a luminance ratio of a first light-emitting element of the plurality of first light-emitting elements and a second light-emitting element of the plurality of second light-emitting elements from a chromaticity signal and a luminance signal which are basis of chromaticity and luminance to be displayed by each of the plurality of pixels so as to correspond to the first light emission color respectively,
determining a light emission intensity corresponding to a luminance signal to be displayed based on the chromaticity of the second light emission color and the luminance ratio,
supplying a drive current having a value corresponding to a light emission color of each of the first light-emitting element and the second light-emitting element to the corresponding one of the first light-emitting element and the second light-emitting element by referring to an information storage configured to store current-chromaticity information for determining a drive current value to light each of the first light-emitting element and the second light-emitting element in accordance with a specific light emission color of each of the plurality of pixels with a first control circuit of the lighting controller, and
controlling a light emission period of the drive current to be supplied to each of the first light-emitting element and the second light-emitting element in accordance with the determined light emission intensity with a second control circuit of the lighting controller.

13. The method for driving a light-emitting device according to claim 12, wherein:
the driving the plurality of first light-emitting elements and the plurality of second light-emitting elements with the lighting controller comprises:
controlling a light emission intensity by pulse-width modulation control in the first subframe with the second control circuit while the first control circuit keeps a drive current of each of the plurality of first light-emitting elements constant, and
controlling, by the first control circuit, a light emission color by a current value for driving each of the plurality of second light-emitting elements and controlling, by the second control circuit, luminance by a light emission period of the current value of each of the plurality of second light-emitting elements controlled by the first control circuit in the second subframe.
